(19) United States
(12) Patent Application Publication
(10) Pub. No.: US 2026/0032938 A1
(43) Pub. Date: Jan. 29, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takato Yamamoto, Kawasaki Kanagawa (JP); Yusuke Kobayashi, Yokohama Kanagawa (JP); Tatsunori Sakano, Shinagawa Tokyo (JP); Ryohei Gejo, Kawasaki Kanagawa (JP); Tomoko Matsudai, Shibuya Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/202,280

(22) Filed: May 8, 2025

(30) Foreign Application Priority Data
Jul. 29, 2024 (JP) 2024-122478

(51) Int. Cl. H10D 12/00

(52) U.S. Cl. CPC H10D 12/416; H10D 12/481

(57) ABSTRACT

A second surface-side region includes a fourth semiconductor layer contacting a second electrode, a fifth semiconductor layer contacting the second electrode, the fifth semiconductor layer having a higher first-conductivity-type impurity concentration than a first semiconductor layer, a sixth semiconductor layer having a lower first-conductivity-type impurity concentration than the fifth semiconductor layer, and a seventh semiconductor layer positioned between the fifth semiconductor layer and the sixth semiconductor layer, the seventh semiconductor layer facing a second gate electrode. An eighth semiconductor layer faces at least the sixth semiconductor layer. A distance in a first direction between the eighth semiconductor layer and the second electrode is less than a distance in the first direction between the eighth semiconductor layer and a first electrode.

### CROSS-REFERENCE TO RELATED APPLICATION

This application is based upon and claims the benefit of priority from Japanese Patent Application No. 2024-122478, filed on Jul. 29, 2024; the entire contents of which are incorporated herein by reference.

### FIELD

Embodiments described herein relate generally to a semiconductor device.

### BACKGROUND

An IGBT (Insulated Gate Bipolar Transistor) that has a double-sided gate structure has been proposed in which gate electrodes are located at the front and back sides of a semiconductor layer.

### BRIEF DESCRIPTION OF THE DRAWINGS

FIG. 1 is a schematic cross-sectional view of a semiconductor device of an embodiment;

FIG. 2 is a schematic plan view of a second surface-side region of the semiconductor device of the embodiment;

FIG. 3A to FIG. 4B are schematic cross-sectional views of the second surface-side region of the semiconductor device of the embodiment;

FIG. 5A to FIG. 6B are schematic plan views of the second surface-side region of the semiconductor device of the embodiment; and

FIG. 7 is a graph showing calculation results of a simulation.

### DETAILED DESCRIPTION

According to one embodiment, a semiconductor device includes a first electrode; a second electrode; a semiconductor part positioned between the first electrode and the second electrode in a first direction, the semiconductor part including a first semiconductor layer of a first conductivity type, a first surface-side region positioned between the first electrode and the first semiconductor layer in the first direction, and a second surface-side region positioned between the second electrode and the first semiconductor layer in the first direction; a plurality of first gate electrodes facing the first surface-side region; a plurality of first insulating films located between the first surface-side region and the plurality of first gate electrodes; a plurality of second gate electrodes facing the second surface-side region in the first direction; and a plurality of second insulating films located between the second surface-side region and the plurality of second gate electrodes, the first surface-side region including a second semiconductor layer facing at least one of the plurality of first gate electrodes via at least one of the plurality of first insulating films, the second semiconductor layer being of a second conductivity type, and a third semiconductor layer contacting the first electrode, the third semiconductor layer being of the first conductivity type and having a higher first-conductivity-type impurity concentration than the first semiconductor layer, the second surface-side region including a fourth semiconductor layer contacting the second electrode, the fourth semiconductor layer being of the second conductivity type, a fifth semiconductor layer contacting the second electrode, the fifth semiconductor layer being of the first conductivity type and having a higher first-conductivity-type impurity concentration than the first semiconductor layer, a sixth semiconductor layer of the first conductivity type, the sixth semiconductor layer having a lower first-conductivity-type impurity concentration than the fifth semiconductor layer, and a seventh semiconductor layer positioned between the fifth semiconductor layer and the sixth semiconductor layer, the seventh semiconductor layer facing the second gate electrode via the second insulating film, the seventh semiconductor layer being of the second conductivity type, the semiconductor part further including an eighth semiconductor layer positioned so that the eighth semiconductor layer faces at least the sixth semiconductor layer in the first direction, the eighth semiconductor layer being of the second conductivity type, a distance in the first direction between the eighth semiconductor layer and the second electrode being less than a distance in the first direction between the eighth semiconductor layer and the first electrode.

Embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

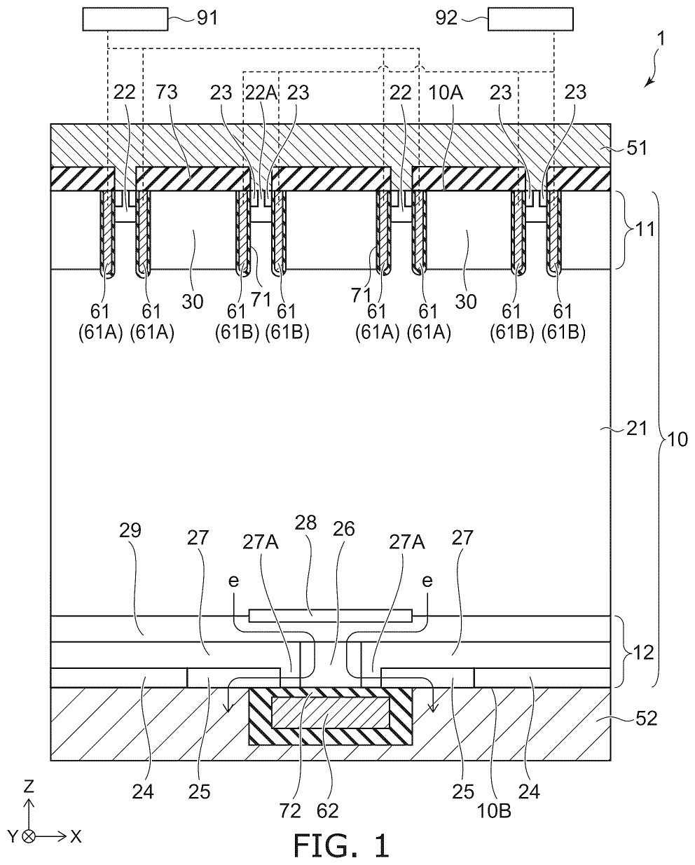

FIG. 1 is a schematic cross-sectional view of a semiconductor device 1 of an embodiment.

The semiconductor device 1 includes a first electrode 51, a second electrode 52, a semiconductor part 10, multiple first gate electrodes 61, multiple first insulating films 71, multiple second gate electrodes 62, and multiple second insulating films 72. The semiconductor device 1 is an IGBT; the first electrode 51 is an emitter electrode; and the second electrode 52 is a collector electrode.

The semiconductor part 10 is positioned between the first electrode 51 and the second electrode 52 in a first direction Z. Two directions orthogonal to the first direction Z are taken as a second direction X and a third direction Y. The second direction X and the third direction Y are orthogonal to each other.

The material of the semiconductor part 10 is, for example, silicon. Or, silicon carbide, gallium nitride, etc., may be used as the material of the semiconductor part 10. In the description of the specification, a first conductivity type of the semiconductor part 10 is taken to be an n-type; and a second conductivity type of the semiconductor part 10 is taken to be a p-type. The first conductivity type may be the p-type; and the second conductivity type may be the n-type.

The semiconductor part 10 includes a first surface 10A, and a second surface 10B positioned at the side opposite to the first surface 10A in the first direction Z. The first electrode 51 faces the first surface 10A in the first direction Z; and the second electrode 52 faces the second surface 10B in the first direction Z.

The semiconductor part 10 includes an n-type first semiconductor layer 21, a first surface-side region 11 positioned between the first electrode 51 and the first semiconductor layer 21 in the first direction Z, and a second surface-side region 12 positioned between the second electrode 52 and the first semiconductor layer 21 in the first direction Z. The first semiconductor layer 21 is a drift layer of an IGBT. The first surface-side region 11 includes the first surface 10A of the semiconductor part 10 and a part of the semiconductor part 10 between the first surface 10A and the first semiconductor layer 21. The second surface-side region 12 includes the second surface 10B of the semiconductor part 10 and a part of the semiconductor part 10 between the second surface 10B and the first semiconductor layer 21.

The first gate electrode 61 faces the first surface-side region 11 of the semiconductor part 10 via the first insulating film 71. The first insulating film 71 is located between the first surface-side region 11 and the first gate electrode 61 and between the first semiconductor layer 21 and the first gate electrode 61. For example, the first gate electrode 61 has a trench-gate structure, and is located, with the first insulating film 71 interposed, inside a trench that extends in the first direction Z from the first surface 10A and extends through the first surface-side region 11. Multiple first gate electrodes 61 are arranged in the second direction X; and the multiple first gate electrodes 61 each extend in the third direction Y. A part of the first semiconductor layer 21 is positioned between the first gate electrodes 61 that are adjacent to each other in the second direction X. An insulating layer 73 is located between the first gate electrode 61 and the first electrode 51 in the first direction Z; and the first gate electrode 61 does not contact the first electrode 51. The first gate electrode 61 may have a planar-gate structure.

The multiple first gate electrodes 61 may include a first gate electrode 61A of a first system and a first gate electrode 61B of a second system. The first gate electrode 61A of the first system is electrically connected with a first gate drive circuit 91; and the first gate drive circuit 91 controls the gate voltage of the first gate electrode 61A of the first system. The first gate electrode 61B of the second system is electrically connected with a second gate drive circuit 92; and the second gate drive circuit 92 controls the gate voltage of the first gate electrode 61B of the second system. The gate voltage of the first gate electrode 61A of the first system and the gate voltage of the first gate electrode 61B of the second system are controllable independently of each other. A pair of first gate electrodes 61 of the same system are adjacent to each other in the second direction X with a second semiconductor layer 22 and a third semiconductor layer 23 interposed.

The first surface-side region 11 includes the p-type second semiconductor layer 22 and the n-type third semiconductor layer 23. The second semiconductor layer 22 is a base layer of the IGBT. The third semiconductor layer 23 is an emitter layer of the IGBT.

The second semiconductor layer 22 is positioned on the first semiconductor layer 21 in the first direction Z and contacts the first semiconductor layer 21. The second semiconductor layer 22 is positioned between the first gate electrodes 61 that are adjacent to each other in the second direction X. The side surface of the second semiconductor layer 22 faces the first gate electrode 61 in the second direction X via the first insulating film 71. The first gate electrode 61 faces the second semiconductor layer 22 in the second direction X via the first insulating film 71. The second semiconductor layer 22 contacts the first insulating film 71.

The n-type impurity concentration of the third semiconductor layer 23 is greater than the n-type impurity concentration of the first semiconductor layer 21. The third semiconductor layer 23 is positioned on the second semiconductor layer 22 in the first direction Z and contacts the second semiconductor layer 22. The third semiconductor layer 23 contacts the first electrode 51 and is electrically connected with the first electrode 51. Two third semiconductor layers 23 that are separated from each other in the second direction X are located between the first gate electrodes 61 that are adjacent to each other in the second direction X. A part 22A of the second semiconductor layer 22 is positioned between the two third semiconductor layers 23. The part 22A of the second semiconductor layer 22 contacts the first electrode 51. The p-type impurity concentration of the part 22A of the second semiconductor layer 22 is greater than the p-type impurity concentration of the part of the second semiconductor layer 22 other than the part 22A. The third semiconductor layer 23 contacts the first insulating film 71.

The first surface-side region 11 may further include a p-type tenth semiconductor layer 30. The tenth semiconductor layer 30 is positioned between the first gate electrodes 61 that are adjacent to each other in the second direction X. The depth from the first surface 10A of the tenth semiconductor layer 30 is greater than the depth from the first surface 10A of the second semiconductor layer 22. The depth from the first surface 10A of the tenth semiconductor layer 30 is less than the depth from the first surface 10A of the first gate electrode 61. The insulating layer 73 is located between the tenth semiconductor layer 30 and the first electrode 51 in the first direction Z; and the tenth semiconductor layer 30 does not contact the first electrode 51. The tenth semiconductor layer 30 does not contact any electrode of the semiconductor device 1, and is in an electrically floating state.

The third semiconductor layer 23 is not located inside the tenth semiconductor layer 30. One side surface among two side surfaces of the first gate electrode 61 in the second direction X is adjacent, with the first insulating film 71 interposed, to the third semiconductor layer 23, the second semiconductor layer 22, and a part of the first semiconductor layer 21 positioned under the second semiconductor layer 22. The other side surface among the two side surfaces of the first gate electrode 61 in the second direction X is adjacent to the tenth semiconductor layer 30 with the first insulating film 71 interposed.

The second gate electrode 62 is a planar-gate structure and faces the second surface-side region 12 in the first direction Z. The second insulating film 72 is located between the second surface-side region 12 and the second gate electrode 62. The second gate electrode 62 is positioned inside the second electrode 52; and the second insulating film 72 is located between the second gate electrode 62 and the second electrode 52. The second insulating film 72 surrounds the upper, lower, and side surfaces of the second gate electrode 62. The second gate electrode 62 does not contact the second electrode 52.

The second surface-side region 12 includes a p-type fourth semiconductor layer 24, an n-type fifth semiconductor layer 25, an n-type sixth semiconductor layer 26, and a p-type seventh semiconductor layer 27.

The p-type impurity concentration of the fourth semiconductor layer 24 is greater than the p-type impurity concentration of the second semiconductor layer 22 and the p-type impurity concentration of the seventh semiconductor layer 27. The fourth semiconductor layer 24 contacts the second electrode 52 and is electrically connected with the second electrode 52. The fourth semiconductor layer 24 is a collector layer of the IGBT. The fourth semiconductor layer 24 is positioned between the second electrode 52 and the seventh semiconductor layer 27 in the first direction Z.

The n-type impurity concentration of the fifth semiconductor layer 25 is greater than the n-type impurity concentration of the first semiconductor layer 21. A part of the fifth semiconductor layer 25 contacts the second electrode 52 and is electrically connected with the second electrode 52. Another part of the fifth semiconductor layer 25 contacts the second insulating film 72. The fifth semiconductor layer 25 is positioned between the second electrode 52 and the seventh semiconductor layer 27 in the first direction Z. A part of the fifth semiconductor layer 25 is positioned between the second insulating film 72 and the seventh semiconductor layer 27 in the first direction Z. The fifth semiconductor layer 25 contacts the fourth semiconductor layer 24 in the second direction X. A part of the fifth semiconductor layer 25 contacts the second insulating film 72.

The n-type impurity concentration of the sixth semiconductor layer 26 is less than the n-type impurity concentration of the fifth semiconductor layer 25 and equal to the n-type impurity concentration of the first semiconductor layer 21. The sixth semiconductor layer 26 faces the second gate electrode 62 in the first direction Z via the second insulating film 72. The sixth semiconductor layer 26 contacts the second insulating film 72 in the first direction Z. The sixth semiconductor layer 26 contacts the seventh semiconductor layer 27 in the second direction X.

The seventh semiconductor layer 27 includes a channel part 27A facing the second gate electrode 62 in the first direction Z via the second insulating film 72. The channel part 27A is positioned between the fifth semiconductor layer 25 and the sixth semiconductor layer 26 in the second direction X and contacts the fifth semiconductor layer 25 and the sixth semiconductor layer 26. In the first direction Z, the seventh semiconductor layer 27 is positioned between the first semiconductor layer 21 and the fourth semiconductor layer 24 and between the first semiconductor layer 21 and the fifth semiconductor layer 25; and the seventh semiconductor layer 27 contacts the fourth semiconductor layer 24 and the fifth semiconductor layer 25. The p-type impurity concentration of the seventh semiconductor layer 27 is less than the p-type impurity concentration of the fourth semiconductor layer 24.

The second surface-side region 12 may further include an n-type ninth semiconductor layer 29. In the first direction Z, the ninth semiconductor layer 29 is positioned between the first semiconductor layer 21 and the seventh semiconductor layer 27 and between the first semiconductor layer 21 and the sixth semiconductor layer 26; and the ninth semiconductor layer 29 contacts the first semiconductor layer 21, the seventh semiconductor layer 27, and the sixth semiconductor layer 26. The n-type impurity concentration of the ninth semiconductor layer 29 is greater than the n-type impurity concentration of the first semiconductor layer 21. The ninth semiconductor layer 29 is a buffer layer of the IGBT. By including the ninth semiconductor layer 29, the ninth semiconductor layer 29 can stop the spreading of a depletion layer in the off-state of the semiconductor device 1; and the thickness (the thickness in the first direction Z) of the first semiconductor layer 21 can be less than when the ninth semiconductor layer 29 is not included.

The fourth semiconductor layers 24, the fifth semiconductor layers 25, and the seventh semiconductor layers 27 are symmetrically arranged in the second direction X with the sixth semiconductor layer 26 interposed. In the semiconductor device 1, the configuration shown in the cross section of FIG. 1 is repeated in the second direction X. The sixth semiconductor layer 26 is positioned between two channel parts 27A that are adjacent to each other in the second direction X. Each configuration in the first surface-side region 11 and each configuration in the second surface-side region 12 are mutually independent. For example, the shapes and arrangement spacing of the multiple first gate electrodes 61 and the shapes and arrangement spacing of the multiple second gate electrodes 62 are configured independently of each other.

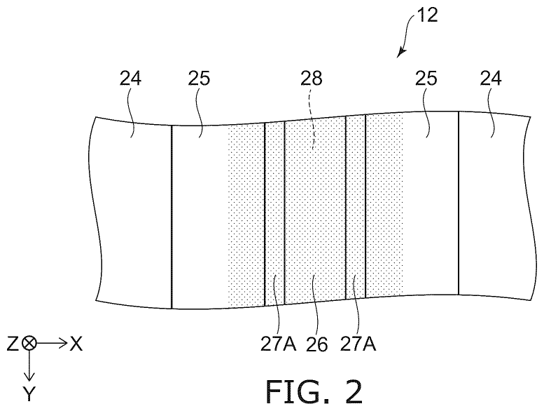

FIG. 2 is a schematic plan view showing an example of the arrangement of the layers of the second surface-side region 12. For example, the channel part 27A extends in the third direction Y between the fifth semiconductor layer 25 and the sixth semiconductor layer 26.

As shown in FIG. 1, the semiconductor part 10 further includes a p-type eighth semiconductor layer 28 positioned so that the eighth semiconductor layer 28 faces at least the sixth semiconductor layer 26 in the first direction Z. The direction from a part of the eighth semiconductor layer 28 toward a part of the sixth semiconductor layer 26 is along the first direction Z. In the example shown in FIG. 1, the eighth semiconductor layer 28 faces the channel part 27A and the second gate electrode 62 in the first direction Z. The direction from a part of the eighth semiconductor layer 28 toward a part of the channel part 27A is along the first direction Z. The direction from a part of the eighth semiconductor layer 28 toward a part of the second gate electrode 62 is along the first direction Z.

The p-type impurity concentration of the eighth semiconductor layer 28 is less than the p-type impurity concentration of the fourth semiconductor layer 24. The eighth semiconductor layer 28 does not contact any electrode of the semiconductor device 1, and is in an electrically floating state. The distance (the shortest distance) in the first direction Z between the eighth semiconductor layer 28 and the second electrode 52 is less than the distance (the shortest distance) in the first direction Z between the eighth semiconductor layer 28 and the first electrode 51. In the semiconductor part 10, the eighth semiconductor layer 28 is more proximate to the interface between the semiconductor part 10 and the second electrode 52 than the interface between the semiconductor part 10 and the first electrode 51.

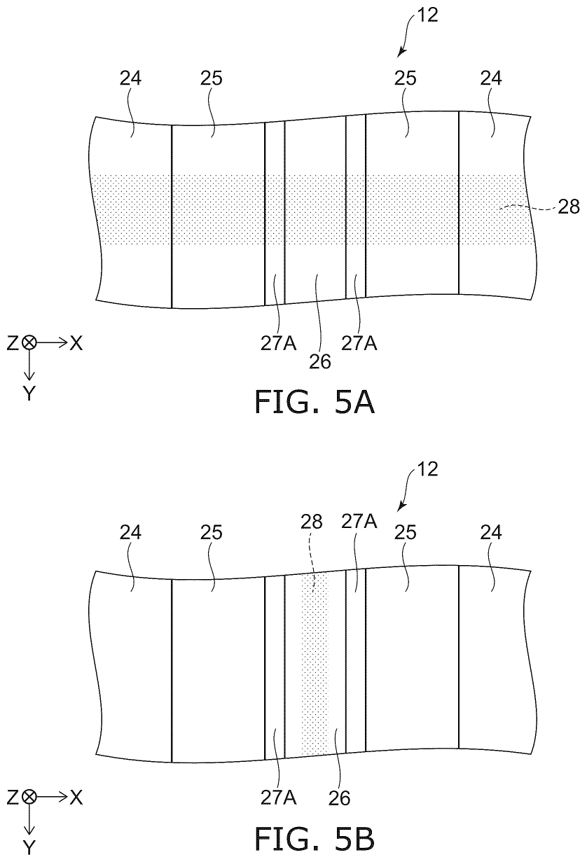

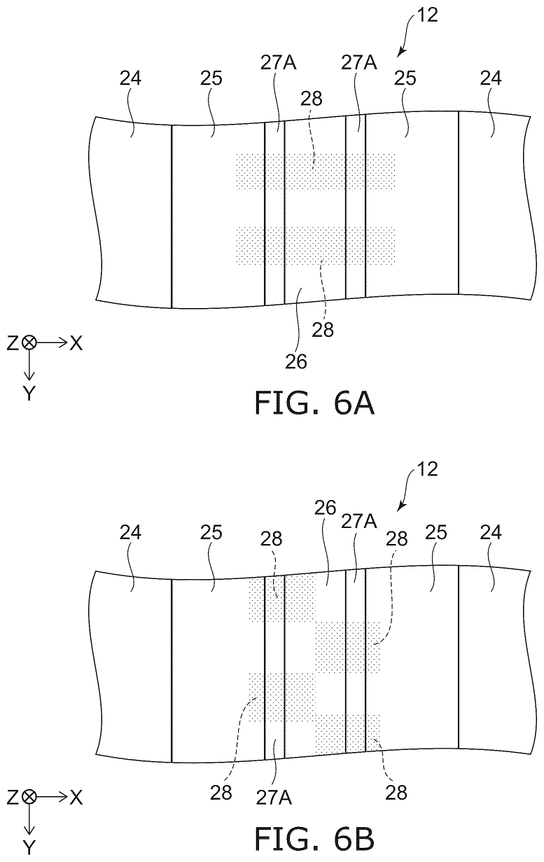

In FIG. 2, the eighth semiconductor layer 28 is illustrated by a dot pattern. The eighth semiconductor layer 28 is illustrated by a dot pattern in FIGS. 5A to 6B below as well. As shown in FIG. 2, the eighth semiconductor layer 28 overlaps at least the sixth semiconductor layer 26 when viewed in plan. In the example shown in FIG. 2, the eighth semiconductor layer 28 overlaps the channel part 27A when viewed in plan.

In the example shown in FIG. 1, the eighth semiconductor layer 28 is positioned at the boundary between the first semiconductor layer 21 and the ninth semiconductor layer 29 and contacts the first semiconductor layer 21 and the ninth semiconductor layer 29. In the example shown in FIG. 1, the eighth semiconductor layer 28 is separated from the sixth and seventh semiconductor layers 26 and 27 and does not contact the sixth and seventh semiconductor layers 26 and 27.

By applying a positive voltage to the second electrode 52 and by applying a gate voltage that is greater than a first threshold voltage to the first gate electrode 61 in a state in which the first electrode 51 is set to 0 V, an n-type first channel (inversion layer) is formed in the part of the second semiconductor layer 22 (the base layer) facing the first gate electrode 61; and the semiconductor device 1 is set to an on-state. In the on-state, an electron current flows between the first electrode 51 and the second electrode 52 via the third semiconductor layer 23 (the emitter layer), the first channel, the first semiconductor layer 21 (the drift layer), the ninth semiconductor layer 29 (the buffer layer), the fourth semiconductor layer 24 (the collector layer), and the fifth semiconductor layer 25. In the on-state, holes are supplied from the fourth and seventh semiconductor layers 24 and 27 to the first semiconductor layer 21; a high-density state of electrons and holes in the first semiconductor layer 21 is created; and a low on-resistance is obtained.

By applying a gate voltage that is less than the first threshold voltage to the first gate electrode 61, the semiconductor device 1 is set to the off-state. The gate voltage of the second gate electrode 62 is turned on to a voltage greater than a second threshold voltage at the timing of turning off the gate voltage of the first gate electrode 61 to be less than the first threshold voltage. The gate voltage of the second gate electrode 62 is turned on directly before, directly after, or simultaneously with turning off the gate voltage of the first gate electrode 61.

According to the example shown in FIG. 1, by turning off the first gate electrode 61B of the second system before the first gate electrode 61A of the first system, the amount of electrons injected into the first semiconductor layer 21 can be reduced, and the turn-off loss can be reduced. Within the period from turn-on to turn-off of the first gate electrode 61A of the first system, the on-period of the first gate electrode 61B of the second system is shorter than the on-period of the first gate electrode 61A of the first system.

When the gate voltage of the second gate electrode 62 is turned on, an n-type second channel (inversion layer) is formed in the channel part 27A of the seventh semiconductor layer 27; and electrons in the first semiconductor layer 21 are discharged into the second electrode 52 via the ninth semiconductor layer 29, the sixth semiconductor layer 26, the second channel, and the fifth semiconductor layer 25. Because electrons in the first semiconductor layer 21 are discharged into the second electrode 52 via a path that does not pass through a p-type semiconductor layer when turning off the semiconductor device 1, the injection of holes from the fourth and seventh semiconductor layers 24 and 27 into the first semiconductor layer 21 can be suppressed, and the turn-off switching loss can be reduced. The gate voltage of the second gate electrode 62 is turned off before turning on the gate voltage of the first gate electrode 61.

The semiconductor device 1 according to the embodiment does not have a reverse conduction function because the semiconductor device 1 does not have a built-in commutation diode connected in parallel with the IGBT when the return current flows from the first electrode 51 (the emitter electrode) to the second electrode 52 (the collector electrode).

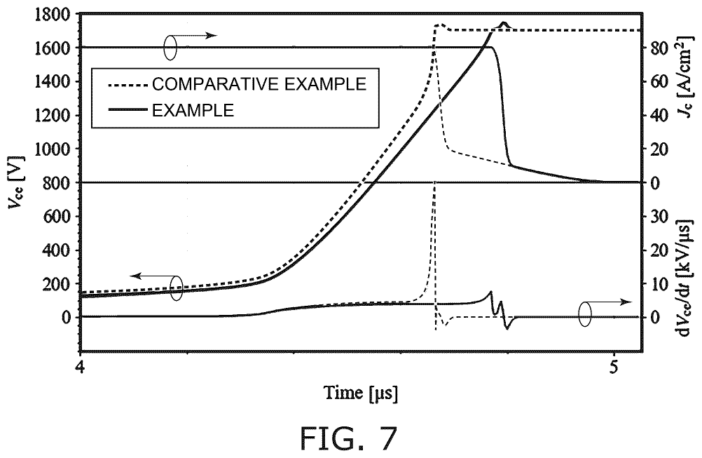

FIG. 7 is a graph showing calculation results of a simulation of a collector-emitter voltage Vce, a collector current density Jc, and dVce/dt for IGBTs of an example and a comparative example. dVce/dt is the change amount of Vce with respect to time when Vce abruptly changes during turn-off. The example is a model of the semiconductor device 1 of the embodiment above; and the results of the example are illustrated by solid lines in FIG. 7. The comparative example differs from the example in that the comparative example does not include the eighth semiconductor layer 28; and the results of the comparative example are illustrated by broken lines in FIG. 7. In the time axis (the horizontal axis), the time at which all of the first gate electrodes 61 have finished turning off is 0 seconds.

For each of the example and the comparative example, the first gate electrode 61B of the second system was turned off and the second gate electrode 62 was turned on at a time of −50 μs. A gate voltage of 15 V was applied to the second gate electrode 62. The n-type impurity concentration of the first semiconductor layer 21 (the drift layer) was set to 2.0×10¹³ cm⁻³. In the example, the p-type impurity concentration of the eighth semiconductor layer 28 had a Gaussian distribution in the first direction Z with a peak of 2.0×10¹⁶ cm⁻³. The p-type impurity concentration of the eighth semiconductor layer 28 was constant in the second direction X. In the example, the eighth semiconductor layer 28 was positioned at the boundary between the first semiconductor layer 21 and the ninth semiconductor layer 29 as shown in FIG. 1. In the example, the eighth semiconductor layer 28 spread 10 μm leftward and 10 μm rightward in the second direction X from the center in the second direction X of the sixth semiconductor layer 26. The width in the second direction X of the sixth semiconductor layer 26 was 4 μm.

According to the comparative example, dVce/dt rose abruptly during turn-off, which may cause problems such as surge voltages, etc. According to the comparative example, the maximum value of dVce/dt during turn-off was 40 kV/μs. It is considered that the abrupt rise of dVce/dt during turn-off was caused by punch-through in a partial region (above the MOSFET at the second surface 10B side of the semiconductor part 10) of the depletion layer spreading through the drift layer. The punch-through occurred above the backside MOSFET at the second surface 10B side, and did not occur in end regions separated from the backside MOSFET in the second direction X.

According to the example as shown in FIG. 1, by including the p-type eighth semiconductor layer 28 at a position such that the eighth semiconductor layer 28 faced at least the sixth semiconductor layer 26, an excessive discharge to the second electrode 52 of electrons e in the region facing the sixth semiconductor layer 26 at turn-off was suppressed. Also, carriers were generated at the upper surface of the eighth semiconductor layer 28 when the depletion layer reached the eighth semiconductor layer 28, which prevented a sudden local reduction of carriers. As a result, dVce/dt was reduced during turn-off. The maximum value of dVce/dt during turn-off in the example was 7.6 kV/μs.

The breakdown voltage, turn-off loss, and on-voltage when Jc=80 A/cm² were simulated for the example and the comparative example. The breakdown voltage of the comparative example was 3,807 V, and the breakdown voltage of the example was 3,822 V. The turn-off loss of the comparative example was 99 mJ/cm², and the turn-off loss of the example was 96 mJ/cm². The on-voltage of the comparative example was 2.16 V, and the on-voltage of the example was 2.10 V. Accordingly, according to the embodiment, dVce/dt can be reduced without sacrificing other characteristics (the breakdown voltage, the turn-off loss, and the on-voltage).

If the eighth semiconductor layer 28 is too distant to the second surface-side region 12 in the first direction Z, punch-through may occur inside the first semiconductor layer 21 below the eighth semiconductor layer 28. It is therefore favorable for the eighth semiconductor layer 28 to be within 10 μm at the first semiconductor layer 21 side in the first direction Z from the boundary between the first semiconductor layer 21 and the ninth semiconductor layer 29.

It is favorable for the p-type impurity concentration of the eighth semiconductor layer 28 to be not less than 1×10¹⁴ cm⁻³ and not more than 1×10¹⁷ cm⁻³.

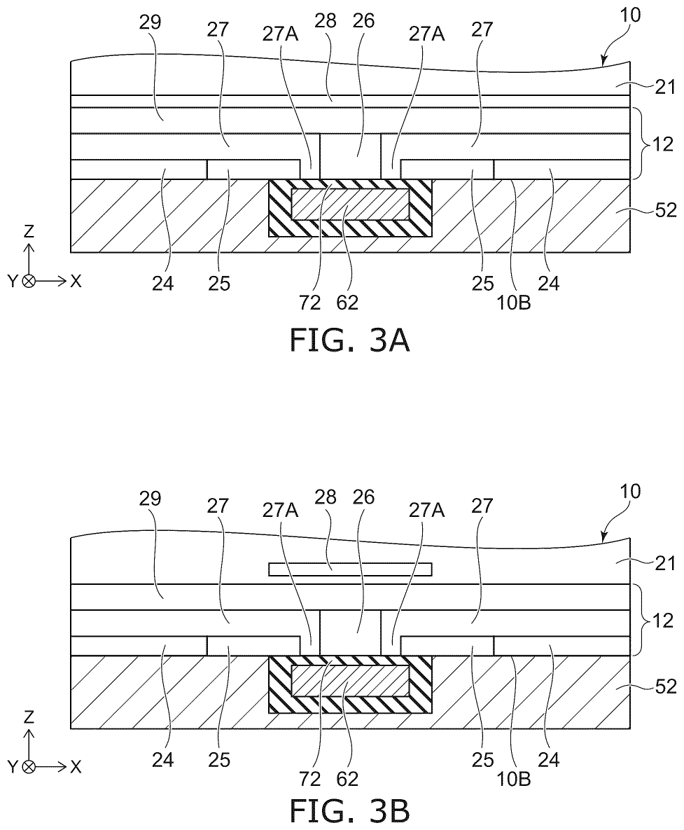

As shown in FIG. 3A, the eighth semiconductor layer 28 may be continuous in the second direction X. In such a case, as shown in FIG. 5A, the eighth semiconductor layer 28 does not spread continuously in the third direction Y when viewed in plan. In other words, the eighth semiconductor layer 28 is arranged in the semiconductor part 10 so that the eighth semiconductor layer 28 does not continuously encompass an entire plane (the XY-plane) perpendicular to the first direction Z inside the semiconductor part 10. The eighth semiconductor layer 28 extends in a direction crossing the third direction Y when the XY-plane is viewed in plan. As a result, a path for the electrons in the first semiconductor layer 21 to be discharged to the second electrode 52 at turn-off is ensured, and the turn-off switching loss can be reduced.

As shown in FIG. 3B, the eighth semiconductor layer 28 may not contact the ninth semiconductor layer 29. In such a case, it is favorable for the eighth semiconductor layer 28 to be within 10 μm at the first semiconductor layer 21 side in the first direction Z from the boundary between the first semiconductor layer 21 and the ninth semiconductor layer 29.

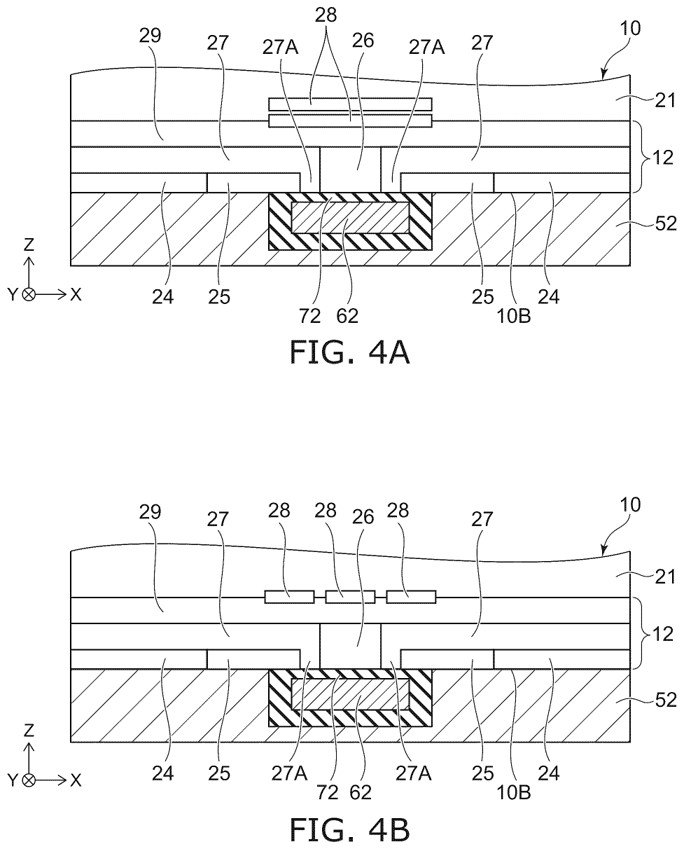

As shown in FIG. 4A, the eighth semiconductor layer 28 may be divided into multiple layers arranged in the first direction Z. It is favorable for at least one of the eighth semiconductor layers 28 to be within 10 μm at the first semiconductor layer 21 side in the first direction Z from the boundary between the first semiconductor layer 21 and the ninth semiconductor layer 29.

As shown in FIG. 4B, the eighth semiconductor layer 28 may be divided into multiple layers arranged in the second direction X. The direction from at least one of the eighth semiconductor layers 28 toward a part of the sixth semiconductor layer 26 is along the first direction Z.

As shown in FIG. 5B, the eighth semiconductor layer 28 may extend in the third direction Y in a region overlapping the sixth semiconductor layer 26 when viewed in plan.

As shown in FIG. 6A, the eighth semiconductor layer 28 may be divided into multiple layers arranged in the third direction Y. The multiple eighth semiconductor layers 28 are arranged in the third direction Y and are separated from each other.

As shown in FIG. 6B, the eighth semiconductor layers 28 may be arranged in a checkered pattern when viewed in plan. A part of the multiple eighth semiconductor layers 28 and another part of the multiple eighth semiconductor layers 28 are arranged in the third direction Y and separated from each other. The direction from the part of the multiple eighth semiconductor layers 28 toward one channel part 27A and the direction from the part of the multiple eighth semiconductor layers 28 toward one sixth semiconductor layer 26 are along the first direction Z. The other part of the multiple eighth semiconductor layers 28 and the other part of the multiple eighth semiconductor layers 28 are arranged in the third direction Y and separated from each other. The direction from the other part of the multiple eighth semiconductor layers 28 toward another channel part 27A and the direction from the other part of the multiple eighth semiconductor layers 28 toward the one sixth semiconductor layer 26 are along the first direction Z. Eighth semiconductor layers 28 included in the part of the multiple eighth semiconductor layers 28 and eighth semiconductor layers 28 included in the other part of the multiple eighth semiconductor layers 28 are alternately arranged in the third direction Y.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode;
a semiconductor part positioned between the first electrode and the second electrode in a first direction, the semiconductor part including
a first semiconductor layer of a first conductivity type,
a first surface-side region positioned between the first electrode and the first semiconductor layer in the first direction, and
a second surface-side region positioned between the second electrode and the first semiconductor layer in the first direction;
a plurality of first gate electrodes facing the first surface-side region;
a plurality of first insulating films located between the first surface-side region and the plurality of first gate electrodes;
a plurality of second gate electrodes facing the second surface-side region in the first direction; and
a plurality of second insulating films located between the second surface-side region and the plurality of second gate electrodes,
the first surface-side region including
a second semiconductor layer facing at least one of the plurality of first gate electrodes via at least one of the plurality of first insulating films, the second semiconductor layer being of a second conductivity type, and
a third semiconductor layer contacting the first electrode, the third semiconductor layer being of the first conductivity type and having a higher first-conductivity-type impurity concentration than the first semiconductor layer,
the second surface-side region including
a fourth semiconductor layer contacting the second electrode, the fourth semiconductor layer being of the second conductivity type,
a fifth semiconductor layer contacting the second electrode, the fifth semiconductor layer being of the first conductivity type and having a higher first-conductivity-type impurity concentration than the first semiconductor layer,
a sixth semiconductor layer of the first conductivity type, the sixth semiconductor layer having a lower first-conductivity-type impurity concentration than the fifth semiconductor layer, and
a seventh semiconductor layer positioned between the fifth semiconductor layer and the sixth semiconductor layer, the seventh semiconductor layer facing the second gate electrode via the second insulating film, the seventh semiconductor layer being of the second conductivity type,
the semiconductor part further including an eighth semiconductor layer positioned so that the eighth semiconductor layer faces at least the sixth semiconductor layer in the first direction, the eighth semiconductor layer being of the second conductivity type,
a distance in the first direction between the eighth semiconductor layer and the second electrode being less than a distance in the first direction between the eighth semiconductor layer and the first electrode.

2. The device according to claim 1, wherein
a second-conductivity-type impurity concentration of the fourth semiconductor layer is greater than a second-conductivity-type impurity concentration of the seventh semiconductor layer.

3. The device according to claim 1, wherein
the second surface-side region further includes a ninth semiconductor layer positioned between the first semiconductor layer and the seventh semiconductor layer,
the ninth semiconductor layer is of the first conductivity type, and
the ninth semiconductor layer has a higher first-conductivity-type impurity concentration than the first semiconductor layer.

4. The device according to claim 3, wherein
the eighth semiconductor layer contacts the ninth semiconductor layer.

5. The device according to claim 3, wherein
the eighth semiconductor layer is within 10 μm at the first semiconductor layer side in the first direction from the boundary between the first semiconductor layer and the ninth semiconductor layer.

6. The device according to claim 1, wherein
the eighth semiconductor layer is arranged in the semiconductor part so that the eighth semiconductor layer does not continuously encompass an entirety of a plane perpendicular to the first direction inside the semiconductor part.

7. The device according to claim 1, wherein
a second-conductivity-type impurity concentration of the eighth semiconductor layer is not less than 1×10¹⁴ cm⁻³ and not more than 1×10¹⁷ cm⁻³.

8. The device according to claim 1, wherein
the eighth semiconductor layer is separated from the sixth and seventh semiconductor layers.

9. The device according to claim 1, wherein
the eighth semiconductor layer is divided into a plurality of layers arranged in the first direction.

10. The device according to claim 1, wherein
the eighth semiconductor layer is divided into a plurality of layers arranged in a second direction orthogonal to the first direction.

11. The device according to claim 1, wherein
the plurality of first gate electrodes includes a first gate electrode of a first system and a first gate electrode of a second system, and
the first gate electrode of the first system and the first gate electrode of the second system are configured so that a gate voltage of the first gate electrode of the first system and a gate voltage of the first gate electrode of the second system are controllable independently of each other.
